(19) United States
(12) Patent Application Publication
(10) Pub. No.: US 2009/0211618 A1
(43) Pub. Date: Aug. 27, 2009

(54) Thermoelectric Device and Thermoelectric Module

(75) Inventor: Koichi Tanaka, Kagoshima (JP)

Correspondence Address: PROCOPIO, CORY, HARGREAVES & SAVITCH LLP, 530 B STREET, SUITE 2100, SAN DIEGO, CA, 92101, US

(73) Assignee: KYOCERA CORPORATION, Kyoto (JP)

(21) Appl. No.: 12/392,543

(22) Filed: Feb. 25, 2009

(30) Foreign Application Priority Data
Feb. 26, 2008 (JP) JP2008-045090

(51) Int. Cl. H01L 35/00

(52) U.S. Cl. 136/200

(57) ABSTRACT

A thermoelectric device and a thermoelectric module are disclosed. The thermoelectric device comprises two thermoelectric materials bonded via first and second bonding surfaces. The first bonding surface comprises a region facing and electrically coupled to the second bonding surface and a region not facing the second bonding surface. Power generation and temperature control extensions to the thermoelectric module are further disclosed.

### CROSS-REFERENCE TO RELATED APPLICATION

The present application claims priority under 35 U.S.C. §119 to Japanese Patent Application No. 2008-045090, filed on Feb. 26, 2008, entitled “THERMOELECTRIC DEVICE AND THERMOELECTRIC MODULE,” the content of which is incorporated by reference herein in its entirety.

### FIELD OF INVENTION

The present invention relates generally to a thermoelectric device and a thermoelectric module, and more particularly relates to a thermoelectric device and a thermoelectric module for temperature control.

### BACKGROUND OF THE INVENTION

In general, a thermoelectric module is formed in such a way that thermoelectric devices are provided between a pair of support substrates and are connected to each other in series by electrodes. Since one support substrate side generates heat and the other support substrate side is cooled by supplying electricity to thermoelectric devices, a thermoelectric module can be used as a cooling device or a heat generating device. In addition, since an electrical potential difference is generated when a temperature difference is provided between two end terminals of a thermoelectric device, the thermoelectric device may be used to generate an electric current based on a temperature difference between the two end terminals. Thus, a thermoelectric module has drawn attention as a module for power generation using waste heat and/or exhaust heat.

In order to improve properties of the thermoelectric module described above, a segment type thermoelectric device has been known in which portions having different compositions and different temperature properties are laminated to each other. The segment type thermoelectric device has relatively superior thermoelectric conversion efficiency. However, there is a need for a further improvement in durability of thermoelectric devices.

### SUMMARY

A thermoelectric device and a thermoelectric module are disclosed. The thermoelectric device comprises two thermoelectric materials bonded via first and second bonding surfaces. The first bonding surface comprises a region facing and electrically coupled to the second bonding surface and a region not facing the second bonding surface. Power generation and temperature control extensions to the thermoelectric device and the thermoelectric module are further disclosed.

A first embodiment comprises a segment type thermoelectric device. The segment type thermoelectric device comprises a first portion comprising a first thermoelectric material, wherein the first portion has a first primary bond surface. The segment type thermoelectric device further comprises a second portion comprising a second thermoelectric material different in composition from the first thermoelectric material. The second portion has a second primary bond surface in contact with at least a part of the first primary bond surface. The first primary bond surface comprises a first facing region which faces the second primary bond surface and which is electrically coupled thereto, and a first non-facing region not facing the second primary bond surface.

A second embodiment comprises a thermoelectric module operable for, without limitation, power generation and temperature control. The thermoelectric module comprises a first substrate, a second substrate, and a plurality of segment type thermoelectric devices arranged between the first substrate and the second substrate. The segment type thermoelectric devices comprise non-facing regions. The thermoelectric module further comprises a plurality of electrodes operable to electrically connect the segment type thermoelectric devices adjacent to each other. The segment type thermoelectric devices comprise a first group of the segment type thermoelectric devices located in a central region of the first substrate and in a central region of the second substrate. The first group comprises a first average area of non-facing regions. The segment type thermoelectric devices further comprise a second group of the segment type thermoelectric devices located in a peripheral region of the first substrate and in a peripheral region of the second substrate. The second group comprises a second average area of non-facing regions. The second average area is greater than the first group average area.

### BRIEF DESCRIPTION OF THE DRAWINGS

Embodiments of the present disclosure are hereinafter described in conjunction with the following figures, wherein like numerals denote like elements. The figures are provided for illustration and depict exemplary embodiments of the disclosure. The figures are provided to facilitate understanding of the disclosure without limiting the breadth, scope, scale, or applicability of the disclosure. The drawings are not necessarily made to scale.

FIG. 1A illustrates a perspective view of an exemplary segment type thermoelectric device according to an embodiment of the disclosure.

FIG. 1B illustrates a cross-sectional view of the exemplary segment type thermoelectric device shown in FIG. 1A.

FIG. 1C illustrates a bottom surface view of the exemplary segment type thermoelectric device shown in FIG. 1A.

FIG. 2A illustrates a cross-sectional view of an exemplary segment type thermoelectric device according to an embodiment of the disclosure.

FIG. 2B illustrates a plan view of a first portion of the exemplary segment type thermoelectric device shown in FIG. 2A.

FIG. 2C illustrates a bottom surface view of a second portion of the exemplary segment type thermoelectric device shown in FIG. 2A.

FIG. 3A illustrates a side view of an exemplary segment type thermoelectric device according to an embodiment of the disclosure.

FIG. 3B illustrates a plan view of a first portion of the exemplary segment type thermoelectric device shown in FIG. 3A.

FIG. 3C illustrates a bottom surface view of a second portion of the exemplary segment type thermoelectric device shown in FIG. 3A.

FIG. 4A illustrates a plan view of a first portion of an exemplary segment type thermoelectric device according to an embodiment of the disclosure.

FIG. 4B illustrates a bottom surface view of a second portion of the exemplary segment type thermoelectric device shown in FIG. 4A.

FIG. 5 illustrates a cross-sectional view of an exemplary segment type thermoelectric device according to an embodiment of the disclosure.

FIG. 6 illustrates a side view of an exemplary segment type thermoelectric device according to an embodiment of the disclosure.

FIG. 7 illustrates a perspective view of an exemplary thermoelectric module according to an embodiment of the disclosure.

FIG. 8 illustrates a cross-sectional view of the exemplary thermoelectric module shown in FIG. 7 taken along a plane surface parallel to a substrate.

### DETAILED DESCRIPTION OF EXEMPLARY EMBODIMENTS

The following description is presented to enable a person of ordinary skill in the art to make and use the embodiments of the disclosure. The following detailed description is exemplary in nature and is not intended to limit the disclosure or the application and uses of the embodiments of the disclosure. Descriptions of specific devices, techniques, and applications are provided only as examples. Modifications to the examples described herein will be readily apparent to those of ordinary skill in the art, and the general principles defined herein may be applied to other examples and applications without departing from the spirit and scope of the invention. Furthermore, there is no intention to be bound by any expressed or implied theory presented in the preceding technical field, background, brief summary or the following detailed description. The present disclosure should be accorded scope consistent with the claims, and not limited to the examples described and shown herein.

Embodiments of the disclosure are described herein in the context of practical non-limiting applications, namely, temperature control and power generation. Embodiments of the disclosure, however, are not limited to such temperature control applications, and the techniques described herein may also be utilized in other applications of thermoelectric device. For example, embodiments may be applicable to thermoelectric refrigeration.

As would be apparent to one of ordinary skill in the art after reading this description, these are merely examples and the embodiments of the disclosure are not limited to operating in accordance with these examples. Other embodiments may be utilized and structural changes may be made without departing from the scope of the exemplary embodiments of the present disclosure.

The following description is presented to enable a person of ordinary skill in the art to make and use the embodiments of the disclosure. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the invention. Thus, embodiments of the present disclosure are not intended to be limited to the examples described herein and shown, but are to be accorded the scope consistent with the claims.

Embodiments of the present disclosure generally relate to a thermoelectric device and a thermoelectric module, and more particularly relates to a thermoelectric device and a thermoelectric module, both of which can be used, for example, without limitation, for temperature control of an air conditioner, a cold temperature chamber, a semiconductor device manufacturing apparatus, an optical detector, a laser diode, and the like. Hereinafter, with reference to the drawings, a segment type thermoelectric device and a thermoelectric module including a plurality of the segment type thermoelectric devices will be described according to various embodiments of the disclosure.

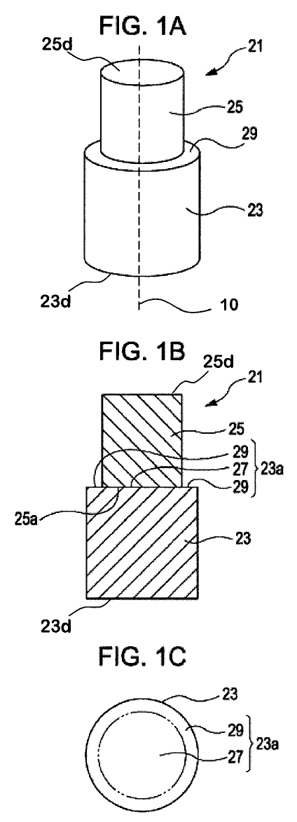

FIG. 1A illustrates a perspective view of an exemplary segment type thermoelectric device 21 according to an embodiment of the disclosure. The segment type thermoelectric device 21 comprises a first portion 23 and a second portion 25 as described in more detail below.

FIG. 1B illustrates a cross-sectional view of the exemplary segment type thermoelectric device 21 shown in FIG. 1A. As shown in FIG. 1B, a primary bond surface 23a of the first portion 23 comprises a facing region 27 and a non-facing region 29. A primary bond surface 25a of the second portion 25 is bonded to the facing region 27 of the first portion 23, and the first portion 23 and the second portion 25 are electrically coupled to each other. Thus, the primary bond surface 23a of the first portion 23 comprises the facing region 27 which faces the primary bond surface 25a of the second portion 25 and is electrically coupled thereto, and the non-facing region 29. The non-facing region 29 does not face the primary bond surface 25a of the second portion 25 and is not responsible for bonding.

A primary component of the second portion 25 comprises a composition of a thermoelectric material which is different from the composition of a thermoelectric material of a primary component of the first portion 23.

During operation of the segment type thermoelectric device 21, either top surface 25d of the second portion 25 has a higher temperature than the bottom surface 23d of the first portion 23, or the bottom surface 23d of the first portion 23 has a higher temperature than the top surface 25d of second portion 25. For example, if the first portion 23 is a high temperature side and the second portion 25 is a low temperature side, the materials used for the first portion 23 and the second portion 25 may be chosen accordingly. Materials that can be used for the first portion 23, may comprise, for example, without limitation, an Mn—Si based, an Mg—Si based, a Si—Ge based, a Pb—Te based, a TAGS based (GeTe—AgSbTe), a Fe—Si based, a Zn—Sb based, a skutterudite-based, a Heusler-based material, or the like. For the second portion 25, a material may be used which has a superior low-temperature properties compared to a material that may be used for the first portion 23. For example, materials that can be used for the second portion 25, may comprise, without limitation, a Bi—Te-based material, a Bi—Sb material, or the like.

The composition of the first portion 23 and/or the second portion 25 of the segment type thermoelectric device 21 can be determined by a chemical analysis such as an induction coupled plasma (ICP) spectroscopic analysis. The analysis may also be performed by an electron probe micro analysis (EPMA) or a fluorescent x-ray analysis.

FIG. 1C illustrates a bottom surface view of the exemplary segment type thermoelectric device 21 shown in FIG. 1A. An area of the primary bond surface 23a of the first portion 23 relative to the primary bond surface 25a of the second portion 25 is illustrated in FIG. 1C. In the embodiment shown in FIG. 1C, the area (i.e., the facing region 27 plus the non-facing region 29) of the primary bond surface 23a of the first portion 23 is larger than an area (i.e., the facing region 27) of the primary bond surface 25a (FIG. 1B) of the second portion 25 (FIG. 1A). The relationship between areas of the primary bond surface 23a of the first portion 23 and the primary bond surface 25a of the second portion 25 is not limited to that described above, and other area relationships may be used. In the embodiment described above, when the second portion 25 is placed on the first portion 23, the non-facing region 29 is formed.

When the segment type thermoelectric device 21 is operated, the first portion 23 comprising the primary bond surface 23a may be set as a high temperature side. The reason for this is that since heat can be dissipated from the non-facing region 29 of the first portion 23, heat dissipation of the segment type thermoelectric device 21 can be effectively performed. In this embodiment, since a central axis 10 of the first portion 23 and that of the second portion 25 coincide with each other, the non-facing region 29 can be formed along an entire peripheral portion of the primary bond surface 23a of the first portion 23 that overlaps the second portion 25. Therefore, heat from the first portion 23 can be more uniformly dissipated.

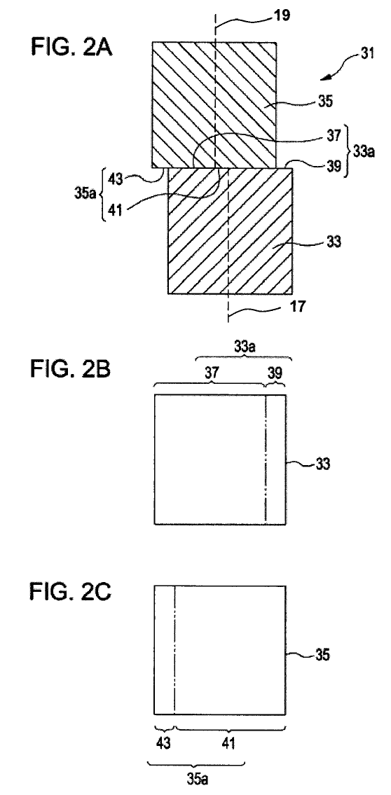

FIG. 2A illustrates a cross-sectional view of an exemplary segment type thermoelectric device 31 according to an embodiment of the disclosure. The segment type thermoelectric device 31 comprises a first portion 33 and a second portion 35. FIG. 2B illustrates a plan view of the first portion 33 of the exemplary segment type thermoelectric device 31 shown in FIG. 2A. FIG. 2C illustrates a bottom surface view of a second portion 35 of the exemplary segment type thermoelectric device 31 shown in FIG. 2A.

The first portion 33 comprises primarily a thermoelectric material. The second portion 35 comprises primarily a thermoelectric material comprising a composition different from that of the thermoelectric material of the first portion 33. A primary bond surface 33a (FIG. 2B) of the first portion 33 and a primary bond surface 35a (FIG. 2C) of the second portion 35 are electrically coupled to each other. The primary bond surface 33a of the first portion 33 comprises a facing region 37 and a non-facing region 39. The facing region 37 faces the primary bond surface 35a of the second portion 35 and is electrically coupled thereto. The primary bond surface 35a of the second portion 35 comprises a facing region 41 and a non-facing region 43. The facing region 41 faces the primary bond surface 33a of the first portion 33 and is electrically coupled thereto. In this embodiment, since the second portion 35 also has the non-facing region 43 as well as the first portion 33, heat in the second portion 35 can also be efficiently dissipated.

Although the first portion 33 and the second portion 35 each have a polygonal column shape, such as a quadrangular column, as shown in FIGS. 2A to 2C, the shapes thereof are not limited thereto. For example, the first portion 33 and the second portion 35 may have a circular cylindrical shape as shown in FIGS. 1A to 1C.

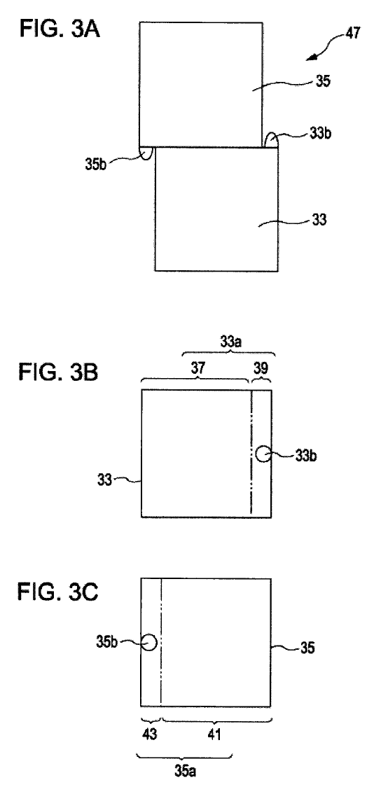

FIG. 3A illustrates a side view showing an exemplary segment type thermoelectric device 47 according to an embodiment of the disclosure. FIG. 3B illustrates a plan view showing a first portion 33 of the exemplary segment type thermoelectric device 47 shown in FIG. 3A. FIG. 3C illustrates a bottom surface view showing a second portion 35 of the exemplary segment type thermoelectric device 47 shown in FIG. 3A. The segment type thermoelectric device 47 shown in FIGS. 3A to 3C may share the same parameters, definition and functionality as explained in the context of discussion of FIGS. 2A to 2C. Therefore, these definitions and the functionalities are not redundantly explained herein.

In the embodiment shown in FIGS. 3A to 3C, a segment type thermoelectric device 47 comprises differences compared to the embodiment shown in FIGS. 2A to 2C. For example, the segment type thermoelectric device 47 further comprises convex parts 33b and 35b provided on the non-facing regions 39 and 43, respectively.

The convex parts 33b and 35b can suppress the relative position between the first portion 33 and the second portion 35 from being shifted from a desired position. As shown in FIGS. 3B and 3C, the convex parts 33b and 35b can be formed on parts of the non-facing regions 39 and 43, respectively. However, the positions of the convex parts 33b and 35b are not limited to that described above. For example, the convex parts 33b and 35b may have belt shapes along regions in which the non-facing regions 39 and 43 are formed, respectively. The convex parts 33b and 35b each having a belt shape can more effectively suppress the first and the second portions 33 and 35 from being shifted.

In the embodiment shown in FIGS. 3A to 3B a cross-sectional area of the first portion 33 is the same as that of the second portion 35. That is, the first portion 33 and the second portion 35 may have the same shape; however, these portions 33/35 are not limited to having the same shape. For example, the cross-sectional area of the first portion 33 may be different from that of the second portion 35. In addition, the height of the first portion 33 and that of the second portion 35 may be different from each other.

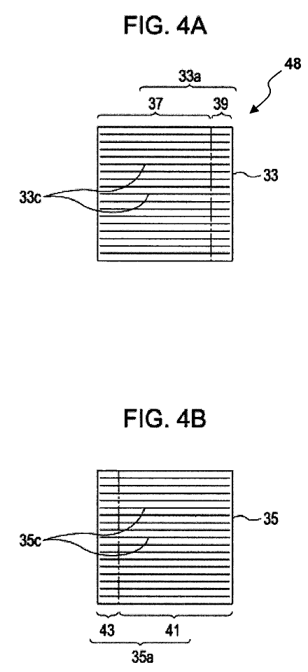

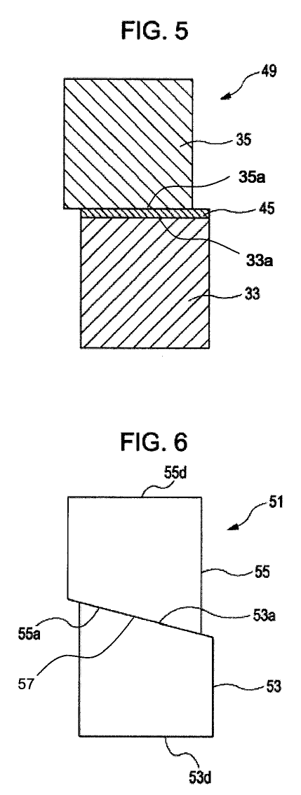

FIG. 4A illustrates a plan view showing a first portion 33 of an exemplary segment type thermoelectric device 48 according to an embodiment of the disclosure. FIG. 4B illustrates a bottom surface view showing a second portion 35 of the exemplary segment type thermoelectric device 48 shown in FIG. 4A.

As shown in FIGS. 4A and 4B, a segment type thermoelectric device 48 according to one embodiment may have grooves 33c in the primary bond surface 33a of the first portion 33 and grooves 35c in the primary bond surface 35a of the second portion 35. When the central axis 17 (FIG. 2A) of the first portion 33 and the central axis 19 (FIG. 2A) of the second portion 35 are shifted relative to each other as shown in FIG. 2A, the grooves 33c and 35c reduce friction resistance between the primary bond surfaces 33a and 35a. That is, when the widths of the non-facing regions 39 and 43 are adjusted, positional adjustment can be performed while the shift in a lateral direction is not taken into consideration. In other words, the positional adjustment of the first portion 33 and the second portion 35 can be performed with good accuracy. As shown in FIGS. 4A and 4B, the grooves 33c and 35c may be formed in the entire primary bond surfaces 33a and 35a, respectively; however, forming the grooves 33c and 35c are not limited thereto. For example, the grooves 33c and 35c may be formed in the facing regions 37 and 41, respectively.

FIG. 5 illustrates a cross-sectional view showing an exemplary segment type thermoelectric device 49 according to an embodiment of the disclosure. As shown in FIG. 5, in a segment type thermoelectric device 49, an intermediate layer 45 may be provided between the first portion 33 and the second portion 35. Moreover, the intermediate layer 45 may be provided between first facing region 37 of the first portion 33 and second facing region 41 of the second portion 35. In this embodiment, although the intermediate layer 45 is formed on the entire primary bond surface 33a (FIG. 5) of the first portion 33, the intermediate layer 45 may also be formed on the primary bond surface 35a (FIG. 5) of the second portion 35.

The intermediate layer 45 may be formed, for example, without limitation, from a metal such as Ti, Ni, Al, Cu, Fe, Ag, Au, Mo, Mn, W, Sn, Si, Pt, Nb, Cr, or Co, or at least two types of aforementioned metals, or an alloy thereof, and the like.

When the central axis 17 (FIG. 2A) of the first portion 33 and the central axis 19 (FIG. 2A) of the second portion 35 are relatively shifted, the intermediate layer 45 reduces the friction resistance between the primary bond surfaces 33a, 35a, and hence the positional adjustment between the first portion 33 and the second portion 35 can be performed with good accuracy.

FIG. 6 illustrates a side view of an exemplary segment type thermoelectric device 51 according to an embodiment of the disclosure. As shown in FIG. 6, in the segment type thermoelectric device 51, an end surface 53d of a first portion 53 and an end surface 55d of a second portion 55 are parallel to each other. A primary bond surface 53a of the first portion 53 and a primary bond surface 55a of the second portion 55 are inclined with respect to the end surfaces 53d and 55d, respectively. Since the primary bond surfaces 53a and 55a are inclined, heat dissipation performance is improved. In addition, the positional adjustment can be easily performed.

In the above embodiments (FIGS. 1 to 6), although the primary bond surfaces 23a/33a/53a of the first portions 23/33/53 and the primary bond surfaces 25a/35a/55a of the second portions 25/35/55 are bonded to each other, the facing regions (e.g., 37 (FIG. 2B), 41 (FIG. 2C)) are not limited thereto, and may be in contact with each other without being bonded or adhered to each other. If the facing regions (e.g., 37, 41) are not bonded to each other, relative positional adjustment between the first portion 23/33/53 and the second portion 25/35/55 of each respective segment type thermoelectric device 21/31/47/48/49/51 can be easily performed when a great number of thermoelectric devices are configured to form, for example, a thermoelectric module 11 as described below. In addition, even when the segment type thermoelectric device (e.g., 21/31/47/48/49/51) is expanded or contracted by heat generated during operation of the thermoelectric module 11, the positions of the first and the second portions are shifted relative to each other, and hence the change in dimension caused by expansion and contraction of the thermoelectric device can be absorbed.

In a typical thermoelectric module, current (I)-voltage (V) characteristics thereof may be unstable depending on usage conditions and/or environmental conditions. Hence, it is desirable to stabilize the I-V characteristics of a thermoelectric module. According to an embodiment of the disclosure, in the thermoelectric module 11 comprising a plurality of thermoelectric devices such as the segment type thermoelectric device 21, since the resistance of the segment type thermoelectric device 21 can be adjusted by appropriately adjusting, for example, the ratio between the facing region 27 and the non-facing region 29, the I-V characteristics can be stabilized.

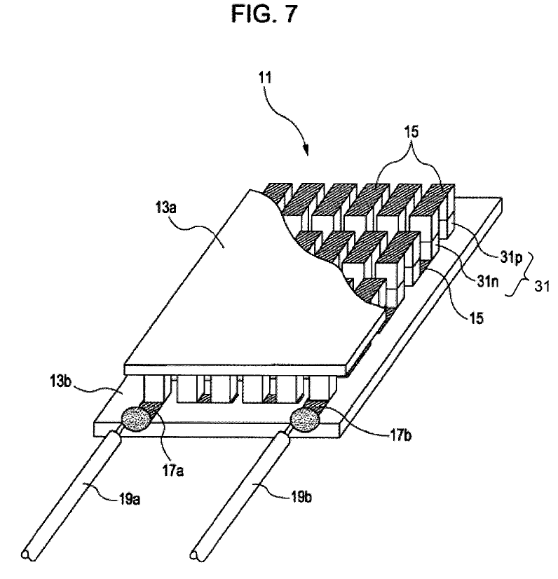

FIG. 7 illustrates a perspective view of an exemplary thermoelectric module 11 according to an embodiment of the disclosure. As shown in FIG. 7, a thermoelectric module 11 comprises a substrate 13a and a substrate 13b, and a plurality of the segment type thermoelectric devices 31 provided therebetween to form a matrix pattern.

Methods for manufacturing a thermoelectric device and a thermoelectric module, according to one or more embodiments of the present disclosure, are discussed below with reference to the segment type thermoelectric device 31 shown in FIGS. 2A to 2C. Although the embodiment shown in FIG. 7 utilizes the segment type thermoelectric device 31, any of other embodiments of the segment type thermoelectric device such as 21/47/48/49/51, and the like may be used.

The segment type thermoelectric devices 31 include an N-type thermoelectric device 31n and a P-type thermoelectric device 31p. The N-type thermoelectric devices 31n and P-type thermoelectric device 31p are alternately located. The N-type thermoelectric devices 31n and the P-type thermoelectric devices 31p adjacent thereto are connected with the electrodes 15 formed on surfaces of the first support substrates 13a and 13b, so that a series circuit is formed.

A plurality of electrodes 15 electrically couple the segment type thermoelectric devices 31 adjacent to each other. The segment type thermoelectric devices 31 (FIGS. 1 to 6) can be connected to the electrodes 15 with solder layers provided therebetween. A terminal electrode 17a is located at one end of the series circuit, and a terminal electrode 17b is located at the other end thereof. Lead wires 19a and 19b are connected to the terminal electrodes 17a and 17b, respectively, with solder or the like provided therebetween.

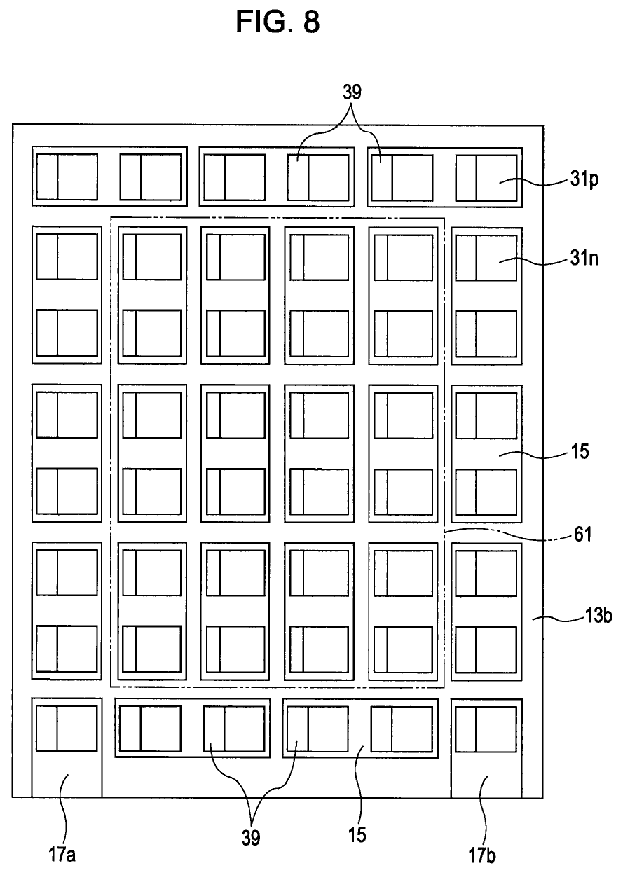

FIG. 8 illustrates a cross-sectional view of the exemplary thermoelectric module 11 shown in FIG. 7 taken along a plane surface parallel to a substrate (13a and 13b in FIG. 7). As shown in FIG. 8, a group of 24 segment type thermoelectric devices 31p and 31n are located along the outermost peripheries (i.e., a peripheral region located outside of a central region 61) of the substrates 13a and 13b. Each of the 24 segment type thermoelectric devices 31p and 31n have a large non-facing region as compared to that of each of a group of 24 segment type thermoelectric devices 31p and 31n located in the central region 61 of the substrates 13a and 13b. Accordingly, heat can be effectively dissipated from the thermoelectric devices located along the outermost peripheries, in each of which the temperature can increase.

The area or average area of the non-facing regions 29/39 of the segment type thermoelectric devices 31p and 31n located along the outermost peripheries (peripheral region) (i.e., not in central region 61) may be greater than the area or average area of the non-facing regions 29/39 of the segment type thermoelectric devices 31p and 31n located in the central region 61.

The segment type thermoelectric devices 31p and 31n which have different areas of the non-facing regions 29/39 may be formed, for example, by filling in dies with raw material. The raw material may be pressurized in the dies to form predetermined shapes. Molding may then be performed using dies having different sizes.

In one embodiment, a thermoelectric module 11 is formed using a plurality of the segment type thermoelectric devices 21 (FIGS. 1A to 1C) in each of which the non-facing region 29 is formed all around the periphery of the primary bond surface 23a of the first portion 23. In the thermoelectric module 11 which has the non-facing region 29 around the primary bond surface 23a of the segment type thermoelectric device 21, a outside portion of the width of the non-facing region 29 of the segment type thermoelectric devices 21 located along the outermost peripheries (i.e., not in central region 61) of the substrates 13a and 13b is more preferably larger than a inside portion of the width of the non-facing region 29 thereof. This allow that heat can be more efficiently dissipated from the non-facing regions 29 which have a large width and which are located along the peripheries of the substrates 13a and 13b to the outsides thereof.

Methods for manufacturing a segment type thermoelectric device 21/47/48/49/51 and a thermoelectric module 11, according to one or more embodiments of the present disclosure, are discussed below with reference to the segment type thermoelectric device 31 shown in FIGS. 2A to 2C.

First, raw material powders for the first and the second portions 33 and 35 are individually prepared. The raw material powders are each obtained in such a way that a crude raw material having a predetermined composition is weighed, is charged into a crucible or the like, and is alloyed by melting, followed by pulverization. After the crude raw material is weighed, since a uniform fine raw material is formed by mixing and pulverizing, a more uniform alloy can be obtained. In addition, since the melting and alloying are performed in a vacuum or an inert gas atmosphere, an alloy can be effectively obtained which is not excessively oxidized and the composition of which is not thereby excessively changed. Furthermore, in order to decrease the amount of oxygen in a raw material, a reduction treatment can be effectively performed in a hydrogen atmosphere for a raw material powder or a molded body.

The raw material thus obtained for the first portion 33 can be filled in a die and can then be pressurized, so that a predetermined shape is formed. Next, the raw material for the second portion 35 is provided on the molded raw material for the first portion 33 and is then pressurized, so that a predetermined shape is formed. The shapes of the dies used for forming the first portion 33 and the second portion 35 can be designed in advance so that the non-facing regions 39/43 are formed. In filling the raw material for the first portion 33 in the die, when a pressing tool having grooves in a pressing surface thereof is used, a thermoelectric device having grooves formed in a facing region 37/41 can be obtained. In addition, when pressing tools inclined with respect to the end surfaces are used, a thermoelectric device having an inclined facing region 57 (FIG. 6) can be obtained.

When the molded body thus obtained is fired by a known method, such as a hot press, a hot forge, a spark plasma sintering (SPS), a pressureless sintering, a gas-pressure sintering, or a hot isostatic pressing (HIP) method, a sintered body can be obtained. This sintered body can be machined into a desired shape, so that the first portion 33 and the second portion 35 are obtained.

Instead of sequentially providing the raw materials for the first portion 33 and the second portion 35 in a die, the first portion 33 and the second portion 35 may be separately formed by a method similar to that described above. After the first portion 33 and the second portion 35 are formed separately, machining can be performed, so that a surface having grooves or a surface inclined with respect to the end surface may be formed. The first portion 33 and the second portion 35 thus formed may be overlapped with other, followed by firing, so that these portions 33 and 35 are united together. In addition, the first portion 33 and the second portion 35 may be placed one on the other at the facing surfaces thereof without being united together.

Next, the N-type thermoelectric devices 31n and the P-type thermoelectric devices 31p are alternately located so as to be electrically coupled to each other in series. A brazing material can be applied on the electrodes 15, and the electrodes 15 can then be placed on the N-type thermoelectric devices 31n and the P-type thermoelectric devices 31p, followed by applying heat and pressure, so that the electrodes 15 are bonded thereto. As the brazing material, in accordance with a working temperature of the thermoelectric device 31 and the heat resistance thereof, an appropriate material may be selected, without limitation, from brazing materials, such as a silver, a copper, a brass, an aluminum, a nickel, a phosphor-copper, and an active metal brazing material; and solder materials, such as an Au—Sn and a Sn—Sb solder materials, and the like.

The electrodes 15 may also be provided by a known method, such as flame spraying, pressure bonding, or bolt bonding. When ceramic substrates integrated with the electrodes 15 are used as the substrates 13a and 13b, the structural preservation and strength thereof can be improved. As the substrates 13a and 13b, an insulating plate primarily composed of a resin or a ceramic, such as alumina, aluminum nitride, silicon nitride, silicon carbide, diamond, or the like, may be used.

In addition, in order to improve workability and structural preservation, a retaining frame may be used. A material for the retaining frame may be appropriately selected, without limitation, from ceramics, such as alumina, aluminum nitride, silicon nitride, silicon carbide, and diamond; metals, such as Ti, Ni, Al, Fe, and Cu; alloys thereof, and the like. This retaining frame is a jig to prevent the segment type thermoelectric devices 31 from being excessively shifted from the positions thereof when brazing is performed or a thermoelectric module is used. In the case of the segment type thermoelectric device 31 in which the first portion 33 and the second portion 35 are bonded to each other, the bond can prevent shifting of the first portion 33 and the second portion 35 relative to each other. However, in the case of the segment type thermoelectric device 31 in which the first portion 33 and the second portion 35 are not bonded to each other, when a filling material is charged inside the retaining frame so as to retain the form, the structure as the module can be retained. In addition, when the retaining frame is divided into two portions such as for the first portion 33 and the second portion 35, the ratio between the facing region 37 and the non-facing region 43 can be easily changed.

The convex parts 33b and 35b (FIGS. 3A to 3C) of the non-facing regions 39 and 43 can be formed by molding or machining as described above. In addition, after the segment type thermoelectric device 47 is formed by providing the second portion 35 on the first portion 33, the convex parts 33b and 35b may be formed by plastic deformation by applying heat and pressure.

Next, the terminal electrodes 17a and 17b of the thermoelectric module 11 thus formed are coupled to lead wires 19a and 19b which take out electricity to the outside or which supply current thereto. Instead of the lead wires, pillars, plates, or blocks may also be used.

In addition, when an ambient gas (e.g. an inert gas such as a nitrogen gas) is enclosed in the thermoelectric module 11 surrounded by a frame member, degradation of thermoelectric module 11 constitutes, such as the segment type thermoelectric devices 31 and the electrodes 15, caused by oxidation and corrosion can be prevented.

In one embodiment, the thermoelectric module 11 according to each of the above embodiments may be mounted in a power generation apparatus as power generation means. This power generation apparatus is called a thermoelectric power generation apparatus, and as the structure of the thermoelectric power generation apparatus, the structure of the thermoelectric module of each of the above embodiments may be used without being changed and/or modified. In addition, when an electric power is not supplied to the thermoelectric module 11, for example, when the first portion 33 is maintained at a high temperature, and the second portion 35 is maintained at a low temperature, an electromotive force proportional to the difference in temperature is generated. Hence, by using the temperature difference, an electric power can be obtained from the thermoelectric module 11 through the terminal electrodes 17a and 17b.

In one embodiment, the thermoelectric module 11 of each of the above embodiments may be mounted in a temperature control apparatus as temperature control means. As the temperature control apparatus, for example, a cooling apparatus using the thermoelectric module 11 as cooling means or a heating apparatus using the thermoelectric module 11 as heating means may be utilized. The cooling apparatus and the heating apparatus as described above may be used, for example, without limitation, for temperature control of an air conditioner, a cool temperature chamber, a semiconductor device manufacturing apparatus, an optical detector, a laser diode, and the like. The temperature control apparatus may include, for example, the thermoelectric module 11, a power supply coupled to the thermoelectric module 11 for supplying electricity thereto, and a controller coupled to the power supply. The controller is operable to control a temperature of the thermoelectric module by controlling a supply of electricity to the thermoelectric module. In this manner, the controller can control the power supply to regulate an amount of heat generation or an amount of heat absorption of the thermoelectric module 11.

For example, when the thermoelectric module 11 is used as cooling means and an electric power is supplied to the thermoelectric module 11, the second portion 35 may be a low temperature side, and hence, an object to be cooled can be directly cooled by this low-temperature second portion 35. Alternatively, after a cooling medium, such as air or water, is cooled by the low-temperature second portion 35, an object to be cooled may be cooled by the cooling medium.

For another example, when the thermoelectric module 11 is used as heating means and an electric power is supplied to the thermoelectric module 11, the first portion 33 may be a higher temperature side, and hence, an object to be heated can be directly heated by this high-temperature first portion 33. Alternatively, after a heating medium, such as air or water, is heated by the high-temperature first portion 33, an object to be heated may be heated by the heating medium.

Table 1 shows data for a segment type thermoelectric device (e.g., 21/31/47/48/49/51) according to various embodiments of the disclosure. As a starting material for a P-type thermoelectric device 31p, a Bi—Sb—Te-based material was prepared for a first portion (e.g., 33), and a material shown in Table 1 was prepared for a second portion (e.g., 35). As a starting material for an N-type thermoelectric device 31n, a Bi—Sb—Te—Se-based material was prepared for a first portion (e.g., 33), and a material shown in Table 1 was prepared for a second portion (e.g., 35).

TABLE 1

| | First portion | Second portion | | | | | | | Cycle test |
|---|---|---|---|---|---|---|---|---|---|
| | Form of non- | | | Form of non-facing | Intermediate | Facing | Non-facing | Bonding at | (number of |
| No. | facing region | P type | N type | region | layer | region | region | interface | cycles) |
| 1 | None | Zn—Sb | Co—Sb | None | — | — | — | Yes | 1000 |
| 2 | FIG. 2 | Zn—Sb | Co—Sb | FIG. 2 | — | — | — | Yes | 2500 |
| 3 | FIG. 1 | Zn—Sb | Co—Sb | None | — | — | — | Yes | 2200 |
| 4 | None | Zn—Sb | Co—Sb | FIG. 1 | — | — | — | Yes | 2000 |
| | | | | (Non-facing region in | | | | | |
| | | | | second portion) | | | | | |
| 5 | FIG. 4 | Zn—Sb | Co—Sb | FIG. 4 | — | Grooves | — | Yes | 2800 |
| 6 | FIG. 6 | Zn—Sb | Co—Sb | FIG. 6 | — | Inclination | — | Yes | 3000 |
| 7 | FIG. 3 | Zn—Sb | Co—Sb | FIG. 3 | — | — | Convex parts | Yes | 2400 |
| 8 | FIG. 5 | Zn—Sb | Co—Sb | FIG. 5 | Ti | — | — | Yes | 2500 |
| 9 | FIG. 5 | Zn—Sb | Co—Sb | FIG. 5 | Ni | — | — | Yes | 2800 |
| 10 | FIG. 5 | Zn—Sb | Co—Sb | FIG. 5 | Al | — | — | Yes | 2500 |
| 11 | FIG. 5 | Zn—Sb | Co—Sb | FIG. 5 | Cu | — | — | Yes | 2600 |
| 12 | FIG. 5 | Zn—Sb | Co—Sb | FIG. 5 | Fe | — | — | Yes | 2500 |
| 13 | FIG. 5 | Zn—Sb | Co—Sb | FIG. 5 | Ag | — | — | Yes | 2200 |
| 14 | FIG. 5 | Zn—Sb | Co—Sb | FIG. 5 | Au | — | — | Yes | 2900 |
| 15 | FIG. 5 | Zn—Sb | Co—Sb | FIG. 5 | Mo | — | — | Yes | 2900 |
| 16 | FIG. 5 | Zn—Sb | Co—Sb | FIG. 5 | Mn | — | — | Yes | 2900 |
| 17 | FIG. 5 | Zn—Sb | Co—Sb | FIG. 5 | W | — | — | Yes | 2000 |
| 18 | FIG. 5 | Zn—Sb | Co—Sb | FIG. 5 | Sn | — | — | Yes | 2000 |
| 19 | FIG. 5 | Zn—Sb | Co—Sb | FIG. 5 | Si | — | — | Yes | 2000 |
| 20 | FIG. 5 | Zn—Sb | Co—Sb | FIG. 5 | Pt | — | — | Yes | 2200 |
| 21 | FIG. 5 | Zn—Sb | Co—Sb | FIG. 5 | Nb | — | — | Yes | 2100 |
| 22 | FIG. 5 | Zn—Sb | Co—Sb | FIG. 5 | Cr | — | — | Yes | 2000 |
| 23 | FIG. 5 | Zn—Sb | Co—Sb | FIG. 5 | Co | — | — | Yes | 2800 |
| 24 | FIG. 5 | Zn—Sb | Co—Sb | FIG. 5 | Ti—Ni | — | — | Yes | 3300 |
| 25 | FIG. 5 | Zn—Sb | Co—Sb | FIG. 5 | Al—Cu | — | — | Yes | 3300 |
| 26 | FIG. 5 | Zn—Sb | Co—Sb | FIG. 5 | Ti—Al | — | — | Yes | 3200 |
| 27 | FIG. 5 | Zn—Sb | Co—Sb | FIG. 5 | Fe—Al | — | — | Yes | 3100 |
| 28 | None | Zn—Sb | Co—Sb | None | — | — | — | No | 1500 |
| 29 | FIG. 2 | Zn—Sb | Co—Sb | FIG. 2 | — | — | — | No | 3000 |
| 30 | FIG. 1 | Zn—Sb | Co—Sb | None | — | — | — | No | 2700 |
| 31 | None | Zn—Sb | Co—Sb | FIG. 1 | — | — | — | No | 2600 |
| | | | | (Non-facing region in | | | | | |
| | | | | second portion) | | | | | |
| 32 | FIG. 4 | Zn—Sb | Co—Sb | FIG. 4 | — | Grooves | — | No | 3300 |
| 33 | FIG. 6 | Zn—Sb | Co—Sb | FIG. 6 | — | Inclination | — | No | 3500 |
| 34 | FIG. 3 | Zn—Sb | Co—Sb | FIG. 3 | — | — | Convex parts | No | 2900 |
| 35 | FIG. 5 | Zn—Sb | Co—Sb | FIG. 5 | Ti | — | — | No | 3000 |
| 36 | FIG. 5 | Zn—Sb | Co—Sb | FIG. 5 | Ni | — | — | No | 3300 |
| 37 | FIG. 5 | Zn—Sb | Co—Sb | FIG. 5 | Al | — | — | No | 3000 |
| 38 | FIG. 5 | Zn—Sb | Co—Sb | FIG. 5 | Cu | — | — | No | 3000 |
| 39 | FIG. 5 | Zn—Sb | Co—Sb | FIG. 5 | Fe | — | — | No | 3000 |
| 40 | FIG. 5 | Zn—Sb | Co—Sb | FIG. 5 | Ag | — | — | No | 2700 |
| 41 | FIG. 5 | Zn—Sb | Co—Sb | FIG. 5 | Au | — | — | No | 3300 |
| 42 | FIG. 5 | Zn—Sb | Co—Sb | FIG. 5 | Mo | — | — | No | 3400 |
| 43 | FIG. 5 | Zn—Sb | Co—Sb | FIG. 5 | Mn | — | — | No | 3300 |
| 44 | FIG. 5 | Zn—Sb | Co—Sb | FIG. 5 | W | — | — | No | 2500 |
| 45 | FIG. 5 | Zn—Sb | Co—Sb | FIG. 5 | Sn | — | — | No | 2500 |
| 46 | FIG. 5 | Zn—Sb | Co—Sb | FIG. 5 | Si | — | — | No | 2400 |
| 47 | FIG. 5 | Zn—Sb | Co—Sb | FIG. 5 | Pt | — | — | No | 2600 |
| 48 | FIG. 5 | Zn—Sb | Co—Sb | FIG. 5 | Nb | — | — | No | 2600 |
| 49 | FIG. 5 | Zn—Sb | Co—Sb | FIG. 5 | Cr | — | — | No | 2500 |
| 50 | FIG. 5 | Zn—Sb | Co—Sb | FIG. 5 | Co | — | — | No | 3300 |
| 51 | FIG. 5 | Zn—Sb | Co—Sb | FIG. 5 | Ti—Ni | — | — | No | 3800 |
| 52 | FIG. 5 | Zn—Sb | Co—Sb | FIG. 5 | Al—Cu | — | — | No | 3700 |
| 53 | FIG. 5 | Zn—Sb | Co—Sb | FIG. 5 | Ti—Al | — | — | No | 3700 |
| 54 | FIG. 5 | Zn—Sb | Co—Sb | FIG. 5 | Fe—Al | — | — | No | 3500 |
| 55 | FIG. 5 | Mn—Si | Mg—Si | FIG. 5 | Ni | — | — | Yes | 2300 |
| 56 | FIG. 5 | TAGS | Pb—Te | FIG. 5 | Ni | — | — | Yes | 2300 |
| 57 | FIG. 5 | Si—Ge | Si—Ge | FIG. 5 | Ni | — | — | Yes | 2600 |
| 58 | FIG. 5 | Fe—Si | Fe—Si | FIG. 5 | Ni | — | — | Yes | 2600 |
| 59 | FIG. 5 | Pb—Te | Pb—Te | FIG. 5 | Ni | — | — | Yes | 2500 |

Next, after predetermined amounts of the materials for the first portions (e.g., 33) were weighed and were then charged in respective crucibles, alloys were formed by melting. After each alloy was pulverized, the particle size was regulated by sieving, so that a raw material powder was obtained. Each raw material powder thus obtained was filled in a die and was pressed by applying a pressure, so that a molded body was obtained. The obtained molded body was heated to about 470° C. in a hot-press firing furnace and was then held for about one hour, thereby forming a sintered body. The obtained sintered body was cut to have a length of about 3 mm, a width of about 3 mm, and a height of about 5 mm, so that the first portion (e.g., 33) was obtained. By a method similar to that described above, the second portions (e.g., 35) were also molded to have various shapes as shown in Table 1.

The first portions (e.g., 33) of the P-type thermoelectric devices and the first portions (e.g., 33) of the N-type thermoelectric devices 31n were arranged, and solder was applied on the end surfaces thereof. Subsequently, after dried electrodes were placed on the solder, heating was performed while a pressure was applied, so that the first portions (e.g., 33) and the electrodes 15 were bonded to each other. In order to improve the wettability of solder, Ni layers were formed on the end surfaces of the first portions (e.g., 33) by a plating method. By a method similar to that described above, electrodes were bonded to the second portions (e.g., 35) of the N-type thermoelectric devices 31n and the P-type thermoelectric devices 31p.

The first portions (e.g., 33) and the second portions (e.g., 35) thus obtained were overlapped to face each other. Lead wires were connected to end portions of terminal electrodes to form a thermoelectric module 11. In order to improve a structural strength, electrodes integrated with alumina support substrates were used.

The bottom surface of the obtained thermoelectric module 11 was cooled by cooling water which was allowed to flow in a heat sink, thereby maintaining the temperature constant. In addition, a heater was provided on the top surface of the thermoelectric module 11. Supply and stop of electric power to this heater is alternately performed, so that a cycle test was performed in which the temperature difference (ΔT) was generated between the top and the bottom surfaces of the thermoelectric module 11. The number of cycles at which the initial resistance was changed by at least 5% was measured.

According to Sample Nos. 2 to 27 and 29 to 59, the number of cycles at which the initial resistance was changed by at least 5% was at least 2,000; hence, superior reliability was obtained. On the other hand, according to Sample Nos. 1 and 28, the number of cycles at which the initial resistance was changed by at least 5% was 1,500 or less; hence, the reliability was inferior.

Hereinafter, the results of the individual samples will be described. In Sample Nos. 2 to 27 and 29 to 59, since the temperature difference was suppressed from being excessively increased, thermal stress and strain generated thereby was reduced, and hence the durability was improved. In particular, in Sample Nos. 5 and 32 in which grooves 33c and 35c (FIG. 4) were provided in a facing region 37/41, Sample Nos. 6 and 33 in which the facing region is inclined, Sample Nos. 7 and 34 in which convex parts 33b and 35b (FIG. 3) were provided in non-facing regions 39/43, and Sample Nos. 8 to 27 and 35 to 59 in which an intermediate layer 45 was provided, the durability was effectively improved, and superior results were obtained.

On the other hand, in Sample Nos. 1 and 28, since a large temperature difference (not shown in FIG. 8), was generated between the first and the second portions 33/35 and large thermal stress and strain were generated. In this manner, cracks were formed in the device, and as a result, the durability was inferior.

Although exemplary embodiments of the present disclosure have been described above with reference to the accompanying drawings, it is understood that the present disclosure is not limited to the above-described embodiments. Various alterations and modifications to the above embodiments are contemplated to be within the scope of the disclosure. It should be understood that those alterations and modifications are included in the technical scope of the present disclosure as defined by the appended claims.

Terms and phrases used in this document, and variations hereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

While at least one exemplary embodiment has been presented in the foregoing detailed description, the present disclosure is not limited to the above-described embodiment or embodiments. Variations may be apparent to those skilled in the art. In carrying out the present disclosure, various modifications, combinations, sub-combinations and alterations may occur in regard to the elements of the above-described embodiment insofar as they are within the technical scope of the present disclosure or the equivalents thereof. The exemplary embodiment or exemplary embodiments are examples, and are not intended to limit the scope, applicability, or configuration of the disclosure in any way. Rather, the foregoing detailed description will provide those skilled in the art with a template for implementing the exemplary embodiment or exemplary embodiments. It should be understood that various changes can be made in the function and arrangement of elements without departing from the scope of the disclosure as set forth in the appended claims and the legal equivalents thereof. Furthermore, although embodiments of the present disclosure have been described with reference to the accompanying drawings, it is to be noted that changes and modifications may be apparent to those skilled in the art. Such changes and modifications are to be understood as being included within the scope of the present disclosure as defined by the claims.

What is claimed is:

1. A segment type thermoelectric device comprising:
a first portion comprising a first thermoelectric material, wherein the first portion comprises a first primary bond surface; and
a second portion comprising a second thermoelectric material different in composition from the first thermoelectric material, wherein the second portion comprises a second primary bond surface in contact with at least one part of the first primary bond surface, and
wherein the first primary bond surface comprises:
a first facing region facing the second primary bond surface and electrically coupled thereto, and
a first non-facing region not facing the second primary bond surface.

2. The segment type thermoelectric device according to claim 1, wherein an area of the first primary bond surface is larger than an area of the second primary bond surface.

3. The segment type thermoelectric device according to claim 1, wherein an area of the first primary bond surface is equal to an area of the second primary bond surface.

4. The segment type thermoelectric device according to claim 1, wherein the second primary bond surface comprises:
a second facing region facing the first primary bond surface and electrically coupled thereto; and
a second non-facing region not facing the first primary bond surface.

5. The segment type thermoelectric device according to claim 4, wherein at least one of the first facing region and the second facing region comprises grooves.

6. The segment type thermoelectric device according to claim 4, wherein the first facing region and the second facing region are bonded to each other.

7. The segment type thermoelectric device according to claim 6, further comprising an intermediate layer between the first facing region and the second facing region.

8. The segment type thermoelectric device according to claim 1, wherein the first portion further comprises a first end surface and the second portion further comprises a second end surface, wherein the first end surface and the second end surface are parallel to each other.

9. The segment type thermoelectric device according to claim 8, wherein the first end surface is inclined with respect to the first facing region.

10. The segment type thermoelectric device according to claim 1, wherein the first non-facing region has a convex part.

11. The segment type thermoelectric device according to claim 10, wherein the convex part comprises a belt shape.

12. The segment type thermoelectric device according to claim 1, wherein the second non-facing region comprises a convex part.

13. The segment type thermoelectric device according to claim 12, wherein the convex part has a belt shape.

14. A thermoelectric module comprising:
a first substrate and a second substrate;
a plurality of segment type thermoelectric devices arranged between the first substrate and the second substrate, wherein the segment type thermoelectric devices comprise non-facing regions; and
a plurality of electrodes operable to electrically couple the segment type thermoelectric devices adjacent to each other,
wherein the segment type thermoelectric devices comprise:
a first group of the segment type thermoelectric devices located in a central region of the first substrate, and in a central region of the second substrate, wherein the first group has a first average area of non-facing regions; and
a second group of the segment type thermoelectric devices located in a peripheral region of the first substrate, and in a peripheral region of the second substrate, wherein the second group has a second average area of non-facing regions, and
wherein the second average area is greater than the first average area.

15. The thermoelectric module according to claim 14, wherein each of the segment type thermoelectric devices comprise:
a first portion comprising a first thermoelectric material, wherein the first portion has a first primary bond surface; and
a second portion comprising a second thermoelectric material different in composition from the first thermoelectric material, wherein the second portion has a second primary bond surface in contact with at least one part of the first primary bond surface,
wherein the first primary bond surface comprises:
a first facing region facing the second primary bond surface and electrically coupled thereto, and
a first non-facing region not facing the second primary bond surface.

16. The thermoelectric module according to claim 14, wherein the electrodes are formed on the first substrate and the second substrate.

17. The thermoelectric module according to claim 14, further comprising terminal electrodes electrically coupled to the electrodes and operable to extract an electromotive force therefrom.

18. The thermoelectric module according to claim 17, wherein the electromotive force is used for power generation.

19. The thermoelectric module according to claim 14, wherein the thermoelectric module is operable to receive a supply of electricity from a power supply coupled hereto, and wherein a controller is coupled to the power supply and is operable to control a temperature of the thermoelectric module by controlling the supply of electricity to the thermoelectric module.
